(19) United States
(12) Patent Application Publication
(10) Pub. No.: US 2009/0310300 A1
(43) Pub. Date: Dec. 17, 2009

(54) Flow-Through Air Conditioning for Electronics Racks

(75) Inventor: Gregory M. Chrysler, Sun Lakes, AZ (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Minebea Co., Ltd., Nagano (JP)

(21) Appl. No.: 12/137,032

(22) Filed: Jun. 11, 2008

(51) Int. Cl. H05K 5/02; F25D 15/00

(52) U.S. Cl. 361/691; 62/119

(57) ABSTRACT

A cabinet adapted with a cooling system is described. Embodiments include electronics cabinets which house electronic equipment. A flow of air is set up in the interior of the cabinet by drawing in ambient air. The incoming air is cooled by an evaporator component of a cooling system. The cooled air cools the electronics and in the process becomes heated air. The heated air serves to cool a condenser component of the cooling system, thereby further heating the heated air. The heated air is then exhausted from the cabinet.

### BACKGROUND OF THE INVENTION

The present invention is directed generally to a cooling systems, and in particular to methods and apparatus for removing heat from cabinets for supporting electronics equipment.

Electronic equipment is typically housed in units referred to variously as electronics cabinets, rack-mount electronic enclosures, electronics racks, and so on. An electronics cabinet typically comprises an enclosure housing electronic devices or components, usually assembled on large printed circuit cards (sometimes referred to as modules) inserted into slots of a card rack. Auxiliary components such as power supplies, power conditioning circuits, and the like are also typically included in the enclosure or housing.

To cool the electronic equipment, fans or blowers, most often positioned in trays, force air over the cards to remove the heat produced by the electronics. FIGS. 7A and 7B, for example, show a typical electronics cabinet 700. The enclosure 702 houses various equipment, including a card cage 714 for supporting electronics modules 730 which plug into a backplane 715 of the card cage and fan trays 712 to circulate cooling air through the interior of the enclosure. An air flow is set up by drawing in ambient air through intake vents 704 and exhausting the heated air through outlet vents 706. Typically, the cooler air enters from the bottom of the cabinet 700 while the resulting heated air exits at or near the top of the cabinet.

Air conditioning systems are available to cool the air within a closed electronics cabinet by re-circulating the air through an air conditioning unit. Conventional air conditioning units are self contained units capable of producing cool air. The units are typically side mounted to the electronics cabinet, recirculating the internal air of the cabinet between the air conditioning unit and the cabinet.

The power density of electronics racks continues to increase, and the need to maintain proper temperature conditions becomes increasingly more important. Racks in large data centers are typically installed in air-conditioned rooms and have ready access to air-conditioned air. Small centers and small/mid-size businesses using single stand-alone racks, on the other hand, oftentimes do not have access to a source of chilled air.

### BRIEF SUMMARY OF THE INVENTION

The present invention includes three major components: (1) an evaporator, or similar device, to remove energy from the air; (2) a compressor, or similar device, to move a coolant through a closed loop; and (3) a condenser, or similar device, to remove energy from the coolant loop. An air conditioning system, using cooling technology not unlike that used in a home refrigerator, is incorporated in an electronics cabinet. A refrigerant circulates through the closed refrigeration loop, from compressor to condenser to evaporator, and back to the compressor. Meanwhile, ambient air enters the electronics cabinet and is cooled by the evaporator. The cooled airflow cools the electronic equipment housed therein. The now-heated airflow is also used to cool the condenser after which the air is exhausted back into the outer environment.

The present invention provides an enhanced method and system for cooling electronics racks for stand-alone or small cluster configurations that house increasingly higher power electronics components. The present invention advances the art of rack cooling by adding a unique air-conditioning system to the rack to cool the electronics housed within the rack.

Advantages of the present invention include:
Provides a lower ambient temperature for the electronics allowing higher device powers to be cooled.
The lower ambient temperature, at nominal device powers, allows the electronic devices to run at lower a temperature for better performance and reliability.
The flow-through configuration of the present invention allows the cooling system to operate at lower power input requirements than existing closed-loop recirculation air-conditioning systems.

### BRIEF DESCRIPTION OF THE DRAWINGS

FIG. 1 is a schematic block diagram of an air-conditioned electronics rack in accordance with an embodiment of the present invention.

FIG. 2 is a graph illustrating the effectiveness of power dissipation provided by an air-conditioned cabinet according to the present invention.

FIGS. 3A and 3B illustrate power requirement comparisons between a conventionally cooled electronics cabinet and an electronics cabinet cooled in accordance with the present invention.

FIG. 4A is a schematic block diagrams of an air-conditioned electronics rack in accordance with an embodiment of the present invention, showing an alternative placement of the evaporator.

FIG. 4B is a schematic block diagrams of an air-conditioned electronics rack in accordance with an embodiment of the present invention, showing an alternative placement of the condenser.

FIG. 5 is a schematic block diagram of an air-conditioned electronics rack in accordance with an embodiment of the present invention, showing the inclusion of a mixer.

FIG. 6A is a schematic block diagram of an air-conditioned electronics rack in accordance with an embodiment of the present invention, showing a configuration of multiple fan units.

FIG. 6B is a schematic block diagram of an air-conditioned electronics rack in accordance with an embodiment of the present invention, showing an alternative configuration of multiple fan units.

FIGS. 7A and 7B are images of a conventional electronics cabinet.

### DETAILED DESCRIPTION OF THE INVENTION

Details of embodiments of the present invention will now be discussed to illustrate the best mode contemplated by the inventor for practicing the present invention, including variations thereof. Structural elements common among the figures are represented by common reference numerals. It will be evident from the explanations that alternatives and substitutions can be made without departing from the scope and spirit of the present invention.

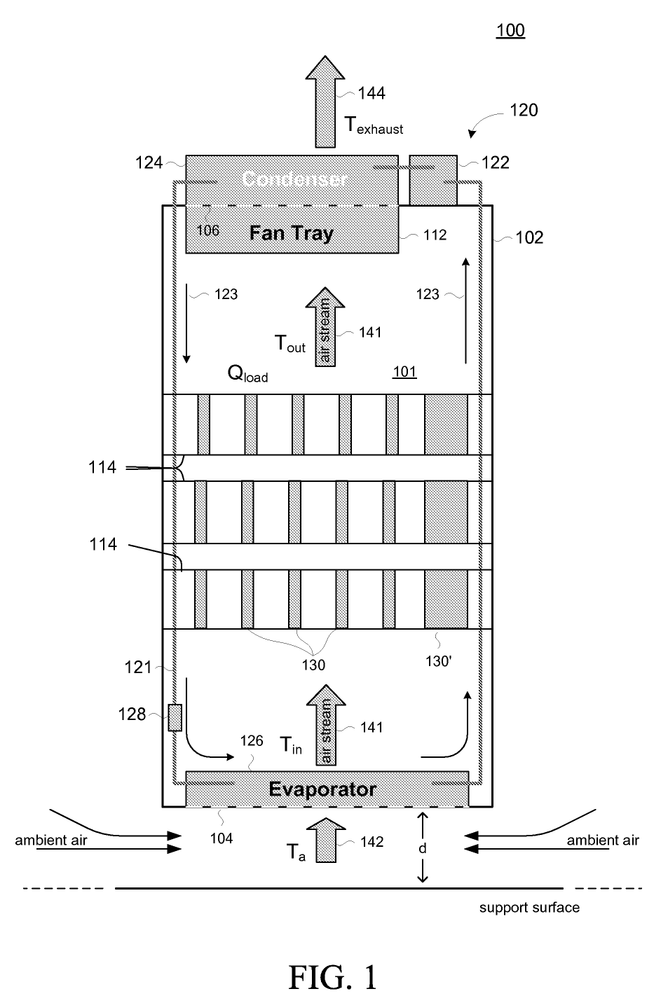

An illustrative embodiment of the present invention is explained in connection with a schematic representation of an electronics cabinet 100 as shown in FIG. 1. It is noted that while embodiments of the present invention are described in the context of cabinets for housing electronic equipment (referred to variously as electronics racks, enclosures and so on), it will be readily apparent from the teachings in the figures and the disclosure that the present invention can be used to house equipment and objects other than electronics equipment for which cooling is desirable. One of ordinary skill will therefore appreciate that the present invention can be adapted for uses other than as enclosures for electronic device components.

In accordance with an embodiment of the present invention, the electronics cabinet 100 depicted in FIG. 1 comprises among other things an enclosure 102 within which various pieces of heat-producing electronic equipment, identified generally by the reference numeral 130, can be housed. Typical electronics cabinets have rack widths (hole-to-hole) of 465 mm, 592 mm, and 745 mm. Typical depths are 17″, 24″, 29″, and 36″. The height can be any height from 2′ to 6′ and taller. These values of course are provided merely as examples of typical cabinet dimensions.

The enclosure 102, in accordance with the present invention, includes an air intake 104 and an air exhaust 106. The air intake 104 and air exhaust 106 can be provided as vented openings formed in the enclosure 102, thus allowing for a flow of ambient air through the interior volume 101 of the enclosure. In the particular embodiment shown in FIG. 1, the air intake 104 is located on the bottom surface of the enclosure 102. This particular electronics cabinet 100, therefore, would be elevated a suitable distance ‘d’ above the surface (e.g., floor, ground, etc.) on which the cabinet is being supported, by support legs (not shown) for example, to allow for an inflow of ambient air 142. Of course, the electronics cabinet 100 can be positioned on a raised floor, such as in a computer room or a telecommunications room, that is equipped with under-floor air distribution. In such a configuration, the suitable distance ‘d’ above the raised floor is likely to be as small as practically possible.

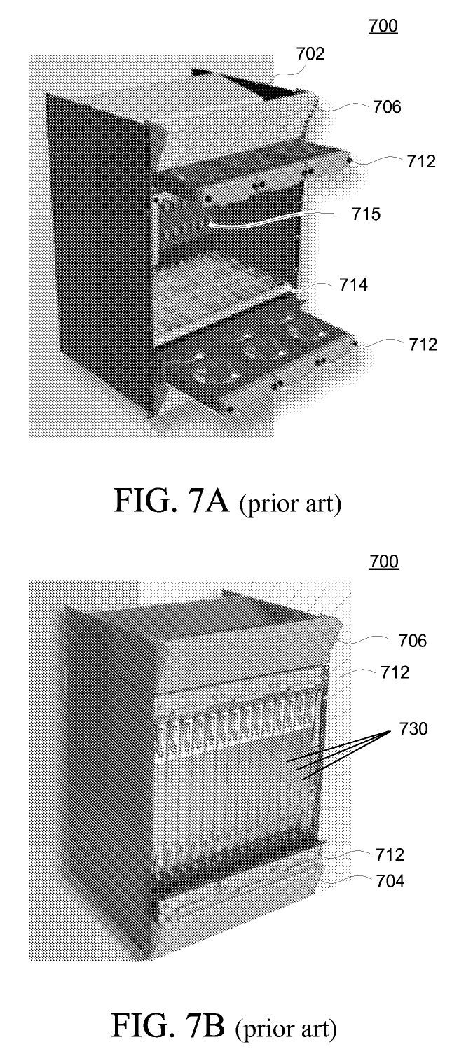

The enclosure 102, in accordance with the present invention, includes one or more racks (or card cages) 114 for supporting the electronic equipment 130 (sometimes referred to as modules). Communication racks used in digital telecommunications, for example, are slotted to receive communication modules (or cards). FIG. 7A shows a conventional enclosure 702 having a slotted rack 714 for receiving a set of modules 730 (FIG. 7B). FIG. 7A shows a backplane 715 into which the modules 730 are plugged. Returning to FIG. 1, the electronic equipment 130 include all manner of electronic components and are not limited to card-type modules. To illustrate this point, FIG. 1 shows components 130′ which can be power supplies and/or power conditioners to provide suitable power for the electronics 130 installed in the respective racks 114.

The enclosure 102, in accordance with the present invention, includes a cooling (air conditioning, refrigeration, etc.) system 120. The cooling system 120 includes a compressor 122, a condenser 124, an evaporator 126, and a throttling device 128 (e.g., expander, valve, etc.). These elements are connected by tubing 121 to form (define) a refrigeration circuit within which a suitable coolant (refrigerant, not shown) is circulated 123. It will understood that a suitable controller, although not shown, is provided to operate the compressor 122 and throttle 128 to operate in a manner to be discussed in more detail below. Technologies such as microcontrollers, FPGAs (field programmable gate arrays), ASICs (application specific ICs), and the like can be used to implement a suitable controller.

A fan unit 112 or other suitable air moving device provides a flow of air within the enclosure 102, to create an air stream (air flow) 141 that flows from the air intake 104 to the air exhaust 106. The fan unit 112 draws ambient air 142 into the enclosure 102 via the air intake 104 to create the airflow 141, which is illustrated in FIG. 1 as flowing through a portion of the interior volume 101 of the enclosure including the volume of space occupied by the racks 114 and electronics 130, 130′. As a result, the airflow 141 created by the fan unit 112 passes over the electronic components 130 toward the air exhaust 106, where it exits and returns to the surrounding environment outside of the enclosure 102.

In accordance with the present invention, the condenser component 124 of the cooling system 120 is disposed at or close to the air exhaust 106. The condenser 124 typically comprises a coil of tubing (condenser coil) that is positioned with respect to the air exhaust 106 such that the outgoing airflow passes across the condenser coil. The evaporator component 126 of the cooling system 120 is disposed at or close to the air intake 104. The evaporator 126 typically comprise a coil of tubing (evaporator coil) that is positioned with respect to the air intake 104 such that the incoming airflow passes across the evaporator coil.

As a matter of convention, the direction of the flow of air 141 from air inlet 104 toward the air exhaust 106 can be referred to herein as the downstream direction, commonly understood nomenclature when discussing the flow of fluids. Hence the condenser 124 is considered to be located downstream of the evaporator 126. Conversely, the evaporator 126 is positioned upstream of the condenser 124. When convenient, the terms upstream and downstream may be used to indicate direction or relative position of components in terms of the direction of the flow of air 141.

The refrigeration circuit shown in FIG. 1 operates in similar manner to that of a conventional home refrigerator or air-conditioner unit. This kind of refrigeration circuit is commonly known as a “vapor compression circuit.” Basically, a refrigerant is pumped internally via the compressor 122 and circulates through the tubing 121. The circuit operates in a “refrigeration cycle” comprising four phases of operation:
1. evaporation phase (heat-input)—A low temperature and low pressure refrigerant in the liquid state is released into the evaporator 126 as a mixture of liquid and vapor. As warm air passes across the surface of the evaporator, the expanding refrigerant absorbs heat from the warm air (cooling the air significantly) and evaporates. The refrigerant leaves the evaporator as an evaporated low pressure gas.
2. compression phase—The compressor 122 pumps the evaporated refrigerant to increase its temperature and pressure, and discharges the high temperature and high pressure gas into the condenser 124.
3. condensation phase—The high temperature and high pressure gaseous refrigerant in the condenser 124 is condensed by passing air across the surface of the condenser, thus removing heat absorbed by the evaporator.
4. pressure reduction phase (throttling)—The throttle 128 is a device that changes the high pressure liquid refrigerant from the condenser 124 to a low pressure mixture of liquid and vapor that once again enters the evaporator 126, where the cycle repeats.

It can be appreciated of course that other kinds of known refrigeration circuits, such as gas compression or thermoelectric, can be readily adapted for use in accordance with the present invention. For example, a gas compression refrigeration circuit comprises elements similar to a vapor compression unit. The equivalent of an “evaporation” phase is achieved in a low pressure, low temperature heat exchanger, though there is no evaporation per se. The equivalent of a “condensation” phase is achieved in a high pressure, high temperature heat exchanger, though there is no condensation per se. A gas compression refrigeration circuit also employs a compressor and a throttle to provide similar functionality as in the vapor compression unit.

A thermoelectric refrigeration circuit is a bit different due to differences in the underlying technology, where cooling is achieved by a device called a thermocouple which provides cooling by a thermoelectric effect known as the Peltier effect. While there is no “evaporation phase” per se, there is a cooling phase which occurs as air passes across the “cold side” of the thermocouple. The air is cooled by directing the air stream across the surface of the cold side of the thermocouple. Similarly, there is no “condensation phase” per se, but the removal of heat absorbed by the cold side of the thermocouple. This heat removal occurs on the “hot side” of the thermocouple. Air passing across the hot side can pick up heat from the hot side of the thermocouple. There is no compression or throttling function as with vapor compression and gas compression devices. However, electrical power must nonetheless be supplied to the thermocouple. Such devices are very well understood and many forms of thermocouples are commercially available.

It will be appreciated from the discussion which follows that alternatives to vapor compression type cooling units, such as the gas compression and thermoelectric types can be readily adapted in accordance with the present invention.

The general operation of the electronics cabinet 100 is as follows: Ambient air 142 is drawn (by operation of the fan unit 112) from the surrounding environment into the interior space 101 of the electronics cabinet 100 at an ambient temperature Tₐ. As the ambient air 142 passes over or through the evaporator 126, energy is extracted from the air lowering its temperature to Tᵢₙ, where Tᵢₙ<Tₐ; i.e., heat exchange occurs between the warm ambient air and the cool surface of the evaporator unit. The resulting air stream 141 of cold air is drawn across the electronics components 130, 130′ where heat exchange between the warm components and the cool air stream serves to cool the components. As the air stream 141 passes across the electronics components 130, 130′, its temperature increases as it picks up heat (Q_{load}) from the components to a value Tₒᵤₜ, where Tₒᵤₜ>Tᵢₙ.

Consider now the flow 123 of refrigerant within the refrigeration circuit. The discussion will begin with the flow 123 of refrigerant as it passes through the throttle 128. The temperature and pressure of the refrigerant are both reduced as it passes through the throttle 128, and so the refrigeration circuit delivers a low temperature (and low pressure) refrigerant to the evaporator 126. The refrigerant flowing through the evaporator 126 absorbs heat from the incoming air 142 as it passes across the outer surfaces of evaporator. This exchange of heat cools the air and heats the refrigerant. From the evaporator 126, the heated refrigerant is pulled into the compressor 122, which compresses the heated refrigerant to raise its temperature and pressure. From the compressor 122 the high temperature and high pressure refrigerant is pushed by operation of the compressor into the condenser 124. The pressurized and high temperature refrigerant dumps its heat to the exiting air stream 141 as it passes across the surfaces of the condenser 124. This exchange of heat cools and condenses the refrigerant and further heats the exiting air stream 141, which exits the electronics cabinet 100 as exhaust air 144 at a temperature Tₑₓₕₐᵤₛₜ(Tₑₓₕₐᵤₛₜ>Tₒᵤₜ). Finally, the refrigerant is pushed through the throttling device 128 where the refrigerant pressure and temperature reduces and is once again delivered to the evaporator 126 where the cycle is repeated.

A feature of the present invention is that the cooling system 120 does not circulate the same air through the electronics cabinet 100, but always draws in fresh air. This is an energy saving feature and makes this cooling approach unique. By comparison, conventional air conditioning systems for electronics racks use external clamp-on side cars that use recirculation of the cooling air.

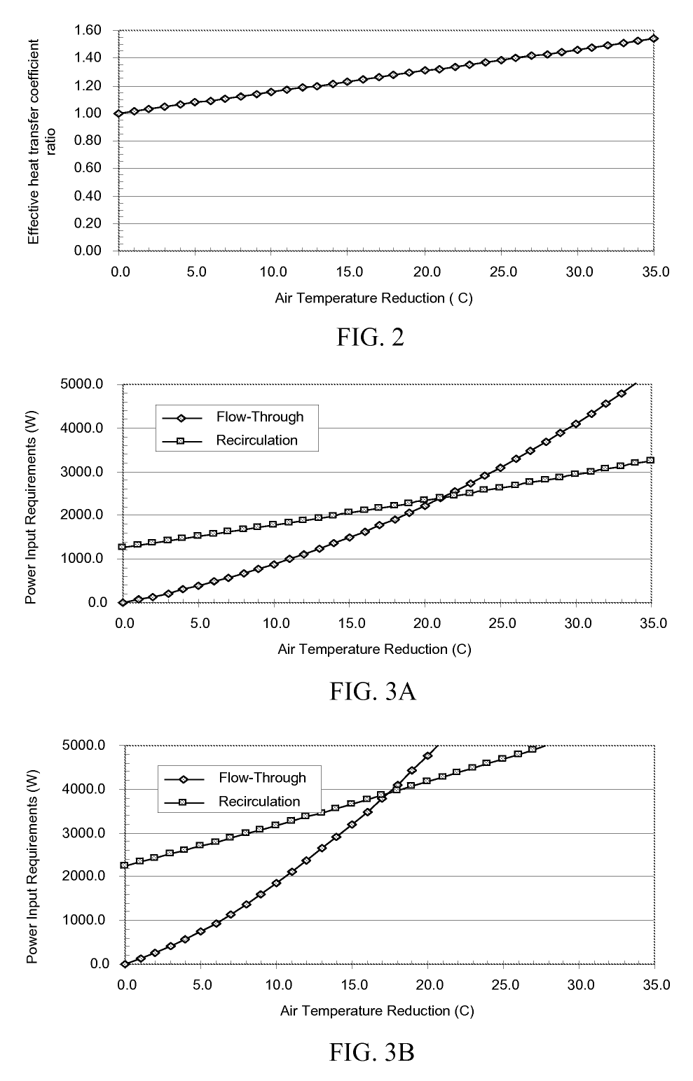

It was discovered that cooling the air entering the electronics rack will allow greater power dissipation from the devices comprising the electronic components 130, 130′. This effect is evidenced in the heat transfer graph of FIG. 2. The ratio of the effective heat transfer coefficient for the air-conditioned rack to the effective heat transfer coefficient for the standard rack is presented. This ratio is a measure of the improvement in cooling, or the increase in power dissipation capability created by the air-conditioned air. As can be seen, even with a modest air temperature reduction of 15° C., the effective convection heat transfer coefficient increases by about 20%.

FIG. 3A compares the cooling requirements for the “flow-through” design of the cooling system 120 of the present invention against the cooling requirements for a conventional recirculation system. The cooling requirement refers to the power consumed by the respective cooling systems (represented on the Y-axis as “power cooling requirement”) to achieve a desired reduction in temperature (represented on the X-axis). The conditions used to generate the plot were: a 4200 W cooling load (the electronics to be cooled) with 35° C. ambient (Tₐ), and 280 CFM (ft³/minute) of air flow through a electronics cabinet. The figure shows that for air temperature reductions of less than about 20° C., the flow-through configuration of the present invention requires less power input to the refrigeration system than a conventional recirculation system.

FIG. 3B shows a comparison between a cooling system 120 according to the present invention and a conventional cooling system for another set of conditions. In this example, the power of the heat load is 7500 W, the ambient is 35° C., and the air flow is 600 CFM. As expected, the input powers (i.e., cooling requirements) are higher in this second case due to the higher cooling load. However, the flow-through configuration still requires less input power than the conventional recirculation configuration, at least up to a 17° C. reduction in air temperature.

In the flow-through system according to the present invention, the refrigerator cools the air, the air cools the electronics, but then the air is effectively dumped. A zero temperature reduction means to simply let the air flow through without powering the flow-through refrigeration system; i.e., the system consumes zero power. In a conventional recirculation system, however, the refrigerator cools the air, the air cools the electronics, but then the air is used to cool the electronics again (and again, and again, etc). The air is heated as it cools the electronics, so power is required to cool the air back down to its starting point (that is zero temperature reduction). Thus, power is consumed by the conventional cooling system, even if zero temperature reduction is desired.

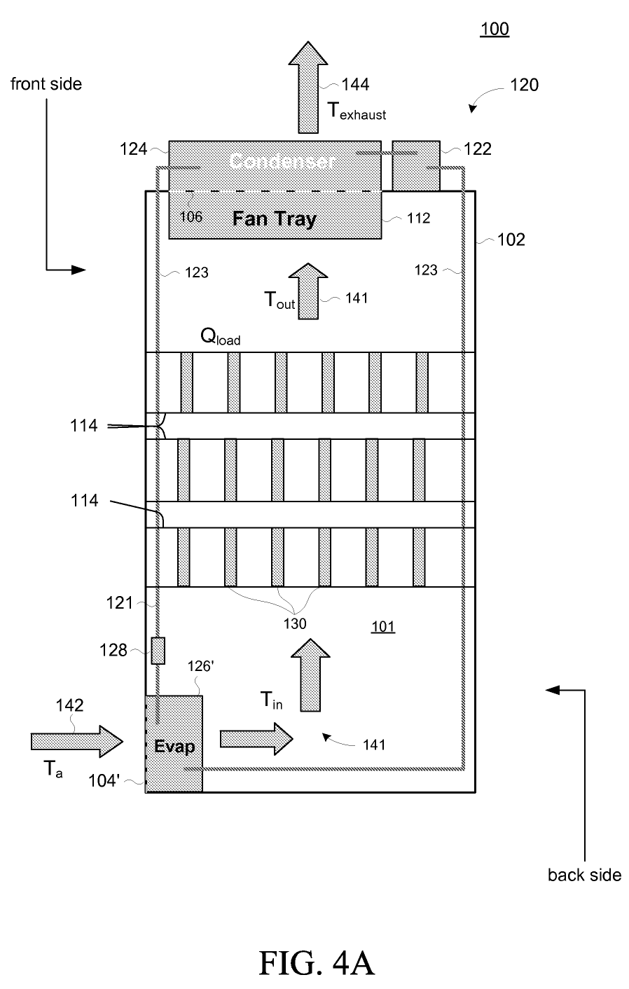

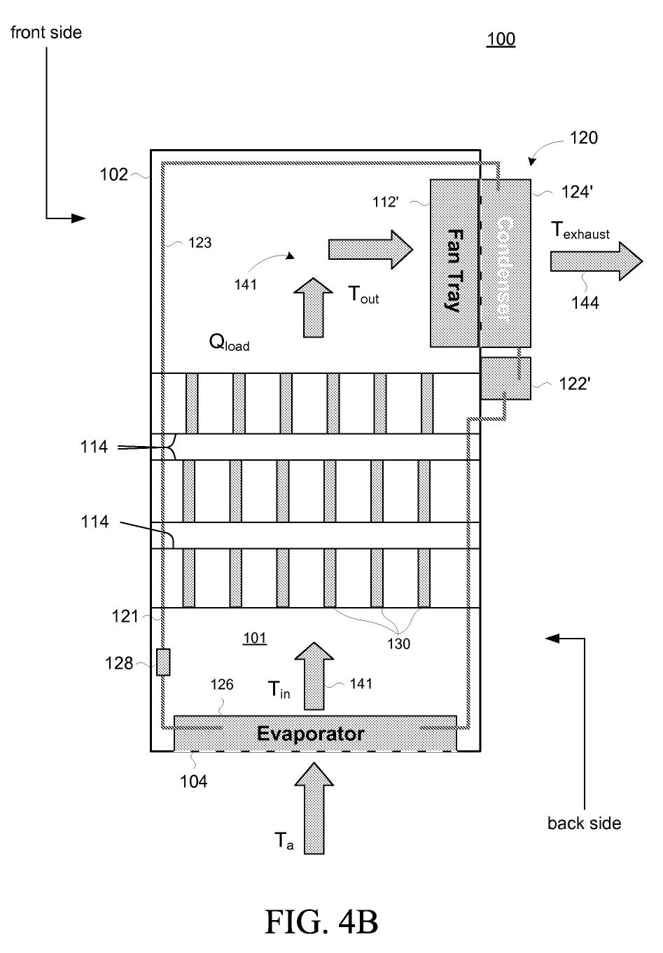

Refer now to FIGS. 4A and 4B for discussion about alternative configurations of the evaporator 126′ and condenser 124. FIG. 4A shows a configuration wherein the evaporator 126′ is positioned on a front side of the electronic cabinet 100. Operation of fan 112 creates an airflow 141 wherein ambient air 142 at temperature Tₐ enters a side-mounted air inlet 104′ into the volume of space 101 within the enclosure 102. The ambient air 142 is cooled by a side-mounted evaporator 102′ and the resulting cool airflow 141 continues downstream into the interior volume of space 101 where it encounters the downstream electronics components 130. As the air flows across and cools the electronics equipment 130, it becomes heated. Continuing in the downstream toward the air exhaust 106, the now-heated airflow 141, drawn by the fan 112, flows across the condenser 124, where as explained above it picks up additional heat from the condenser before exiting as exhaust air 144 at a temperature Tₑₓₕₐᵤₛₜ.

FIG. 4B shows a configuration wherein the condenser 124′ is arranged on a rear (back) side of the electronics cabinet 100. The compressor 122′ and fan tray 112′ are correspondingly repositioned as well. Based on the teachings of these figures it should be apparent that the evaporator, the condenser, and the compressor can be arranged on the enclosure 102 in any of a number of combinations in order to suit the particular constraints of a given installation. For example, an electronics cabinet 100 can be configured such that the evaporator 126 is located on the front panel and the condenser 124 is located back panel. Still other configurations are possible; e.g., the evaporator 126 and condenser 124 can be positioned on the side panels, and so on. In addition, the compressor 122 can be located in any convenient spot within enclosure 102, with the understanding of course that its position in the refrigeration circuit relative to the other elements in the circuit is maintained.

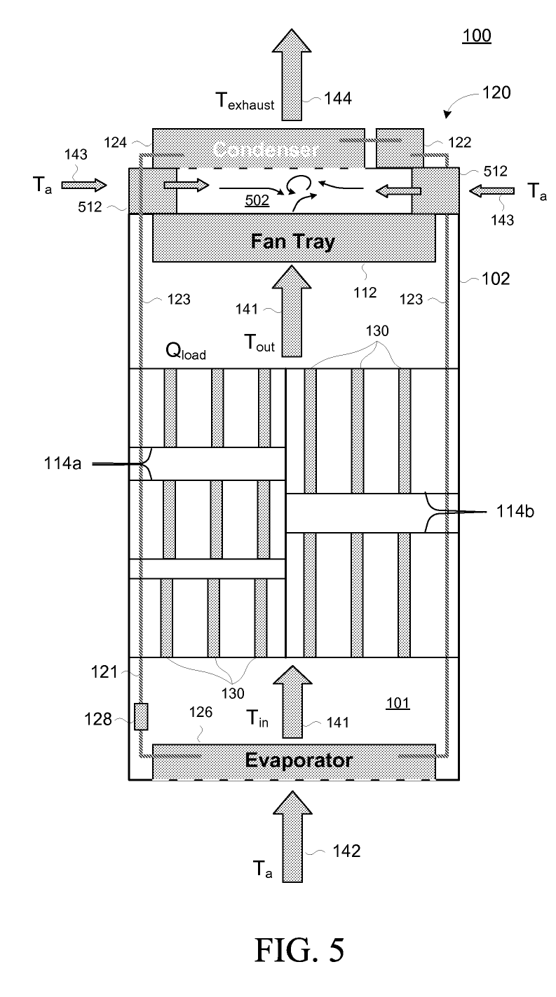

Turn now to FIG. 5 for a description of an alternative embodiment of the present invention. As explained above, the incoming ambient air 142 that passes across the evaporator 126 located at the air inlet 104 and enters the interior space 101 as a cool air stream 141 and chills the downstream rack(s) of electronic equipment 130. The air stream 141 is heated to a temperature Tₒᵤₜ by the operation of the heat exchange between the air stream and the electronic equipment 130. Nonetheless, the condenser 124 still operates at a temperature T_{condenser} higher than the air stream 141 (T_{condenser}>Tₒᵤₜ). Thus, when the air stream 141 flows across the condenser 124, in accordance with the present invention, the condenser 124 can still be cooled.

Under certain operating conditions or environments, however, such as high electronics power and/or high ambient temperature, the air stream 141 leaving the rack(s) 114 can be too hot to adequately cool the condenser 124. For such situations, additional fans/blowers 512 can be positioned just upstream of the condenser 124 to mix some fresh (cooler) ambient air 143 with the flow of air 141 leaving the electronics section in a chamber 502 (Tₐ<Tₒᵤₜ) to provide more effective cooling of the condenser. FIG. 5 shows air flows 143 entering chamber 502 by operation of the fans 512. The air flows 143 mix with the heated air flow 141 when it is drawn into chamber 502 by operation of fan 112. The chamber 502 is illustrated schematically in the figure and thus does not show any details. However, it can be appreciated that there might additional structure in the chamber 502 (e.g., baffles or the like) to facilitate mixing of the incoming ambient air 143 and the incoming heated air flow 141.

FIG. 5 also illustrates the idea that different rack configurations can be accommodated. In FIG. 5, the rack configuration includes racks 114a for holding or supporting components of a given form factor and racks 114b for holding or supporting components of another form factor. It can be appreciated from the teachings in this figure that most any configuration of racks 114 can be accommodated by an electronics cabinet in accordance with the present invention.

In the foregoing figures, one fan tray 112 is shown positioned near the air exhaust 106. It is understood that these figures are merely schematic representations, and that actual specific configurations of fans for creating a suitable airflow within the enclosure 102 will depend largely on the physical configuration of the enclosure, the physical configuration of internal components, the desired cooling effect, and so on. The size of the enclosure, the size of card cages, and the type and number of components being cooled would be typical factors to consider.

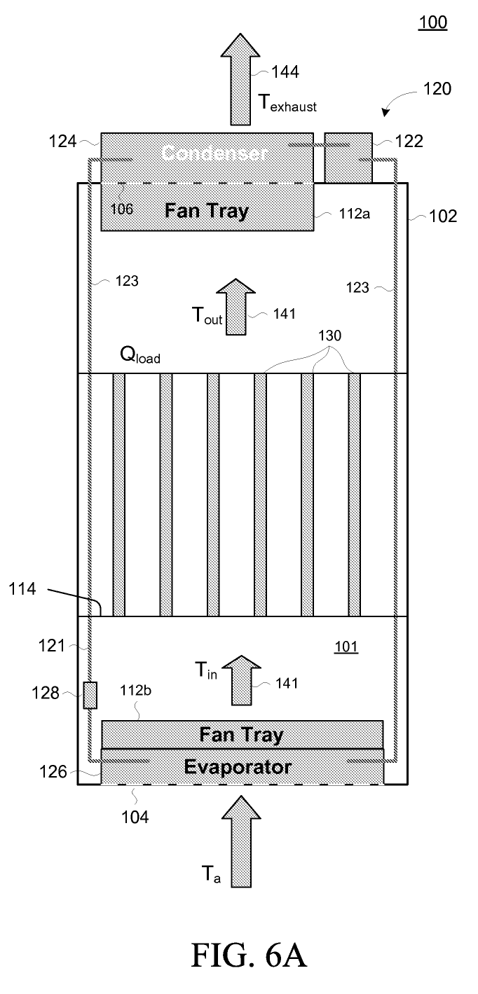

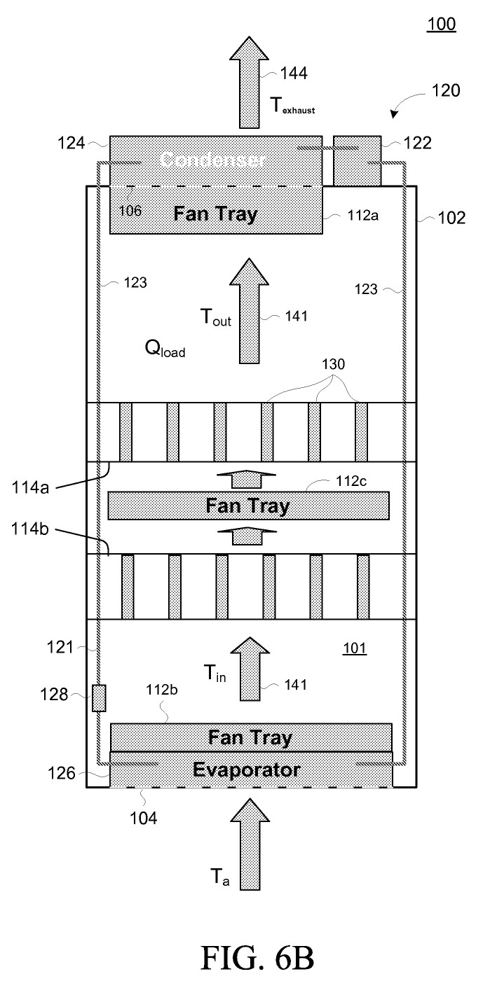

For example, depending of the volumetric air flow requirements and air pressure drop requirements, a second fan tray can provided. Referring to FIG. 6A, an example of such an alternative arrangement of fans is shown. The figure shows the use of two fan trays 112a, 112b. Having additional fan trays can improve the airflow 141 through the interior space 101 of the enclosure 102. This may be called for if the interior is cluttered with equipment to the extent that a suitable flow of air is not easy to set up. The additional fan(s) would facilitate establishing a flow of air through the rack of electronic equipment 130.

FIG. 6B shows yet another configuration of fans. Here, fan tray 112c is provided between racks 114a and 114b. This configuration might be useful where the racks 114a, 114b support densely packed electronics modules 130, where an additional fan such as fan 112c would facilitate the flow of air through the modules. Based on the teachings of FIGS. 6A and 6B, it should be apparent that still other fan configurations are possible.

The foregoing figures teach various embodiments of different aspects of the present invention. It can be appreciated that these teachings can be combined in many ways to obtain configurations of cooling cabinets suited for different operating environments and operating conditions. For example, the alternative evaporator and condenser configurations represented by FIGS. 4A and 4B can be combined with the alternative fan tray configurations represented by FIGS. 6A and 6B. The air mixing aspect of the present invention illustrated by example in FIG. 5 can be combined with any of the configurations represented by example in the other figures. One of ordinary skill will appreciate that still other combinations of configurations can be obtained without departing from the scope and spirit of the present invention as claimed in the claims which follow.

What is claimed is:

1. A cabinet comprising:
an enclosure having an air inlet and an air outlet;
a refrigeration circuit having a compressor, a condenser, an expansion region, and an evaporator, wherein a refrigerant circulating therein is discharged from said compressor and passes respectively through said condenser, said expansion region, and said evaporator; and
a fan unit to produce a flow of air that enters said enclosure at said air inlet, passes through a volume of space within said enclosure, and exits said enclosure at said air outlet,
wherein said evaporator is disposed in fluid contact with said flow of air as said flow of air enters said enclosure at said air inlet thereby cooling said flow of air, whereby objects disposed downstream of said flow of air are cooled by said flow of air,
wherein said condenser is disposed in fluid contact with said flow of air as said flow of air exits said enclosure at said air outlet.

2. The cabinet of claim 1 further comprising a mixer disposed upstream of and proximate said condenser, said mixer configured to mix said flow of air with an additional flow of air.

3. The cabinet of claim 2 wherein said additional flow of air is ambient air.

4. The cabinet of claim 1 further comprising at least one additional fan unit disposed along a path of said flow of air to facilitate circulation of said flow of air.

5. The cabinet of claim 1 wherein said flow of air that enters said enclosure at said air inlet is ambient air.

6. The cabinet of claim 1 wherein said objects include electronic components.

7. An enclosure comprising:
an air conditioning system comprising a first heat exchanger and a second heat exchanger, wherein said first heat exchanger absorbs heat, wherein said second heat exchanger releases heat absorbed by said first heat exchanger;
a fan disposed within said enclosure and configured to provide a flow of air that enters into said enclosure via an inlet and exits from said enclosure via an outlet;
a support disposed within a path of said flow of air between said inlet and said outlet,
wherein said first heat exchanger is disposed within a path of said flow of air proximate said inlet to absorb a quantity of heat from said flow of air,
wherein said flow of air cooled by said first heat exchanger cools one or more heat-generating objects supported by said support member,
wherein said second heat exchanger is disposed within a path of said flow of air proximate said outlet to release a quantity of heat from said condenser to said flow of air.

8. The enclosure of claim 7 wherein said support member is configured to support electronic equipment.

9. The enclosure of claim 7 wherein said fan is proximate said inlet, the enclosure further comprising another fan disposed proximate said outlet to facilitate said flow of air.

10. The enclosure of claim 9 further comprising at least a third fan to further facilitate said flow of air.

11. The enclosure of claim 7 further comprising a mixer disposed proximate said outlet, said mixer configured to input ambient air and to mix said ambient air with said flow of air, wherein said second heat exchanger releases said quantity of heat from said condenser into said flow of air mixed with said ambient air.

12. The enclosure of claim 7 wherein said inlet is disposed at a bottom portion of said enclosure, wherein said outlet is disposed at a top portion of said enclosure.

13. The enclosure of claim 7 wherein said air conditioning system is a vapor compression type of air conditioning system.

14. The enclosure of claim 7 wherein said air conditioning system is a gas compression type of air conditioning system or a thermoelectric type of air conditioning system.

15. A method for cooling a cabinet comprising:
operating an air cooling system comprising a condenser unit and an evaporator unit configured as a fluid circuit, including circulating a coolant in said fluid circuit; and
creating an air flow through a volume of space within said cabinet, including:
drawing air into an interior space of said cabinet to produce a flow of air;
passing said air across said evaporator unit to cool said flow of air;
passing said flow of air through said volume of space to cool one or more heat-generating components disposed therein within thereby warming said flow of air;
passing said flow of air across said condenser unit to cool said coolant flowing therethrough; and
exhausting said flow of air out of said cabinet exiting from said condenser unit,
wherein said flow of air serves to cool said one or more heat-generating components and participates in a condensation phase of an operating cycle of said air cooling system.

16. The method of claim 15 further comprising operating a first fan unit to effect said steps of passing said flow of air.

17. The method of claim 16 wherein said first fan unit is operated proximate to said evaporator unit, the method further comprising operating a second fan unit proximate said condenser unit.

18. The method of claim 17 further comprising operating at least a third fan unit to further facilitate said flow of air.

19. The method of claim 15 further comprising drawing an additional amount of air into said cabinet, wherein said passing said flow of air across said condenser unit includes mixing said flow of air with said additional amount of air.
